(19) United States
(12) Patent Application Publication
(10) Pub. No.: US 2005/0248022 A1
(43) Pub. Date: Nov. 10, 2005

(54) High data rate chip mounting

(75) Inventors: Nader E. Badr, Ames, IA (US); William C. Black, Ames, IA (US)

Correspondence Address: KINNEY & LANGE, P.A., THE KINNEY & LANGE BUILDING, 312 SOUTH THIRD STREET, MINNEAPOLIS, MN, 55415-1002, US

(73) Assignee: Northern Microdesign, Inc., Ames, IA (US)

(21) Appl. No.: 11/125,826

(22) Filed: May 10, 2005

Related U.S. Application Data
(60) Provisional application No. 60/569,838, filed on May 10, 2004.

(51) Int. Cl. H01L 23/48

(52) U.S. Cl. 257/690

(57) ABSTRACT

An electronic circuit component mounting system for mounting electronic circuit components on a substrate for an electronic circuit component having an electrically conductive bonding pad on an interconnection surface thereof and a substrate having a trace supporting surface with an electrically conductive trace thereon. The interconnections between the traces and pads are formed so that they differ in shape or position, or both, along the lengths thereof as positioned over a conductive layer, but adjacent pairs used to carry differential signals may not be positioned over such a layer.

### CROSS-REFERENCE TO RELATED APPLICATION

This application claims the benefit of Provisional Application No. 60/569,838 filed May 10, 2004 for “HIGH DATA RATE CHIP MOUNTING”.

### BACKGROUND OF THE INVENTION

The present invention relates to monolithic integrated circuit chips which transmit and receive high data rate or high frequency signals during operation and, more particularly, to such chips as mounted in an assembly with interconnections to such chips for these signals.

High data rate, and so high frequency, monolithic integrated circuit chips are typically mounted on a printed circuit board. The chip is connected to the circuit board interconnection conductors, or traces, through chip interconnections. As the data signals transmitted through the chip interconnection are provided at higher data bit rates, there is a need to improve the chip interconnection performance to avoid signal distortions.

At low frequencies and low data bit rates, a conductive chip interconnection can be considered as a small lumped resistor, and a small lumped capacitor with negligible phase shift in the signals therein. This is due to the fact that the wavelength of the signal can be very long compared to the actual distance the signal travels, and the signal is virtually the same along all points of this actual distance traveled. However, when the data bit rate increases, the wavelength of the data signal can be short enough that the voltage of the signal along a conductive chip interconnection is not equal at all points. In this case the chip interconnection behaves as a transmission line of a wavelength or multiple wavelength extent.

A transmission line can be modeled by a set of electrically passive components. The series resistive effect of the line can be modeled as a resistance per unit length R(Ω/m). The series inductive effect of the line can be modeled as an inductance per unit length L(Ω/m). The parasitic capacitive effect of the single line can be modeled as a capacitance per unit length C(F/m). The conductive effect of the insulating material between the transmission line and other conductive material, such as a reference plane, can be modeled as G(1/Ωm). The set of electrically passive components that represent a transmission line can have the component values arranged in a matrix format that contains the values R, L, C, and G. This set is called the RLCG matrix, and can provide a mathematical model of a transmission line as is developed below.

The characteristic impedance Zₒ is the impedance of a single transmission line over ground that occurs when the line is infinitely long. In this case when a signal is imposed on the transmission line, it does not reflect back from its end. An impedance difference, or an impedance discontinuity, occurs when there is a difference between the transmission line impedance and the impedance of a circuit joined to that line. The best approach to reduce or avoid the resulting signal reflections is to minimize this difference or eliminate it if possible. Zₒ can be calculated as

$${Z}_{o} = \sqrt{( \frac{R + jω L}{G + jω C} )}$$

If a pair of conductive coupled lines over ground is used to transmit signals, then signals can be sent differentially over the conductor pair. The impedance of a single conductor in this case is called the odd mode characteristic impedance, Z_{odd}. If the same signal is simultaneously transmitted on both lines, i.e. both conductors act as a single line, the impedance of a single conductor in this case is called the even mode characteristic impedance, Zₑᵥₑₙ.

The commonly used chip package based assembly structure, such as a ceramic or plastic structure, has the chip positioned in the center of the package. Bonding wires, thin wires with traditionally circular cross-sections, are connected as the chip interconnections from the chip bonding pads in the chip top metal layer to corresponding lead pins in the package structure that connect the package to the printed circuit board.

In another chip assembly configuration, the chip is placed on top of a printed circuit board in a board mounted configuration as seen in FIG. 1. In this configuration, bonding wires are bonded to the corresponding chip bonding pads in the chip top metal layer as the chip interconnections. The other end of the bonding wire is attached to the chip printed circuit board interconnection trace. The elimination of pin leads and packaging as described above helps in reducing the chip interconnection parasitic inductance, resistance, capacitance and susceptance as a result of the bond based wire connection being used instead.

Another arrangement is to use wedge wires as the chip interconnections with rectangular cross-sections having fixed cross-sectional dimensions along the extent thereof that extend from the printed circuit board trace to the corresponding chip bonding pad. These are used instead of bonding wires for the chip interconnections in the board mounted configuration for connecting board traces and corresponding chip pads.

The conventional board mounted assembly described above for mounting chips has an initially unconnected integrated circuit chip or die positioned on the top trace supporting surface of a printed circuit board. The circular cross-section bonding wires are then connected from chip bonding pads in the chip top metal layer to corresponding trace pads on the printed circuit board with the wire following the shape of a vertical arc as shown in FIG. 1. The lengths of such bonding wires can be several millimeters. Extensive variations of the elevation of the bond wire arcs above the board occur along the spatial path each wire follows from its corresponding trace pad to its corresponding chip pad.

Impedance variations, or discontinuities, occur in the board mounted assembly at the trace pads if the impedances of the board traces there and the impedances of the corresponding bonding wires are different. Impedance discontinuities also occur when the impedance at the chip bonding pads is different from the impedance of the corresponding bonding wires. Impedance variation occurs along a bonding wire because of the changing elevation of the bonding wire over its spatial path from the board trace pad to the chip pad. There are several factors that affect the impedance variations for bonding wire chip interconnections: the interconnection cross-section geometry, the interconnection elevations over its path, the interconnection conductor material used, and the adjacent insulator dielectric material.

This board mounting configuration leads to a considerable variation in Z_{odd}, Zₑᵥₑₙ, and Zₒ characterizing the transmission line provided by the bonding wire along its path. The variation in Zₒ results in distortions of signals from one end of the line to the other end of the line. This can be seen in the resulting “ringing” in the signal when it contains high frequency components all of which is desirable to reduce or eliminate.

### BRIEF SUMMARY OF THE INVENTION

The present invention provides an electronic circuit component mounting system for mounting electronic circuit components on a substrate for an electronic circuit component having an electrically conductive bonding pad on an interconnection surface thereof and a substrate having a trace supporting surface with an electrically conductive trace thereon. A mounting location on the substrate for the component is spaced apart from an electrically conductive layer and the component is supported on the mounting location so as to leave the interconnection surface of the component at a distance from the conductive layer that is different from the distance between the trace supporting surface and the conductive layer. An electrically conductive interconnection conductor has its ends in bonds the pad and the trace so that there is a varying separation distance between the interconnection conductor and the layer between said bonds with the interconnection conductor having a distance in its cross sections between the bonds that varies with the separation distance. The interconnection conductor can be a plate having a truncated end wedge shape to have a varying width along its length with a thickness that can be constant or vary along its length.

In another embodiment, the mounting system has a substrate with a pair of adjacent traces and a component to be mounted thereon with a pair of adjacent pads. A pair of interconnection conductors each extends between a corresponding one of the traces and a corresponding one of the pads with a varying distance between them over their lengths and a thickness that varies over its length. These interconnection conductors can be provided mounted on the substrate over a spaced apart conductive layer with a width that also varies with its length. The interconnection conductor can be a plate having a truncated end wedge shape to have a varying width along its length with a thickness that can be constant or vary along its length. The interconnection conductors can each be a plate having a truncated end wedge shape to have a varying width along its length with a thickness that varies along its length.

### BRIEF DESCRIPTION OF THE DRAWINGS

FIG. 1 shows a side view of a conventionally mounted monolithic integrated circuit chip on a printed circuit board,

FIGS. 2A, 2B, 2C and 2D show a side view, two top views, and a further side view of mounted monolithic integrated chips in and on a printed circuit board embodying the present invention,

FIG. 3 shows a top view and a cross section view of chip interconnection conductors,

FIG. 4 shows a graph with plots of the results of use of a conventional chip mounting arrangement,

FIG. 5 shows a graph with plots of the results of use of the present invention,

FIG. 6 shows a graph with plots of the results of use of the present invention,

FIG. 7 shows a graph with plots of the results of use of the present invention,

FIG. 8 shows a graph with plots of the results of use of the present invention,

FIG. 9 shows a graph with plots of the results of use of a conventional chip mounting arrangement,

FIG. 10 shows a graph with plots of the results of use of the present invention,

FIG. 11 shows a graph with plots of the results of use of the present invention,

FIG. 12 shows a graph with plots of the results of use of the present invention, and

FIG. 13 shows a graph with plots of the results of use of the present invention.

### DETAILED DESCRIPTION

The elevation of the top surface of a monolithic integrated circuit chip mounted on a printed circuit board relative to the top surface of a printed circuit board supporting traces is an important factor in the performance of the chip interconnections between the chips bonding pads and the board trace pads. When the chip upper surface with the bonding pads is lowered with respect to the top surface of the printed circuit board supporting the traces to which the bonding pads are to be connected, the chip interconnection elevation peak is brought closer to the ground plane of the printed circuit board as is the elevation of the chip interconnection overall along the spatial paths of thereof from the board to the chip. As a result, the self-capacitance of the chip interconnection to ground is increased. In addition, the self-inductance to ground of the chip interconnection is decreased because of the decreased elevation peak of the wire conductor. The result of lowering the elevations of the chip interconnection along its path from the board to the chip to reduce them with respect to the board ground plane from those occurring in conventionally mounted chips on a board is a decrease in the characteristic impedance of the transmission line provided by that interconnection.

In the case of a conductor wire pair, the horizontal spacing between the wire conductors decreases along the path of each from the board to the chip. This is due to the minimum spacing between adjacent trace pads on the board being typically an order of magnitude larger than the spacing between the corresponding adjacent chip bonding pads.

In a differential wire conductor pair for a board mounted configuration having the chip surface closer to the ground plane of the board there are two factors that affect Zₒ, Zₑᵥₑₙ, and Z_{odd}. The first factor is the narrowing of the spacing as just described between the two wire conductors along the paths thereof from the board to the chip. The second factor is the earlier described lowering of the elevations of both wire conductors along the spatial paths thereof from the board to the chip.

This narrowing of the spacing between the conductors increases the mutual inductance between the two conductors, and increases the mutual capacitances between the conductors by different factors depending on the geometry of the conductors such as radius, width, or thickness of their cross sections.

This lowering of the elevations of both wire conductors along the paths thereof from the board to the chip has the same effect as in the case of a single conductor. Zₑᵥₑₙ decreases because of the increase of the self-capacitance to ground of the wire conductor.

In high data rate chip interconnections, both ends of the chip interconnection transmission lines should have, ideally, the same characteristic impedances. This means that Z_{odd} should also be the same for both ends of the line, and Zₑᵥₑₙ should be the equal at both ends of the line. As a result, Zₒ will be identical for both ends of the line. The difference between the characteristic impedances of both lines should be minimized. Otherwise a mismatch occurs and signals transmitted through such chip interconnection may as a result suffer distortion.

Placing the chip on top of the printed circuit board in the conventional board mounted assembly configuration results in smaller self-capacitance of the chip interconnection transmission lines from the chip to ground than if a lower wire relative elevation arrangement would be used. In turn, this leads to increasing the characteristic impedance of the chip interconnection along its path from the board to the chip. The characteristic impedance of a chip interconnection transmission line at the chip bonding pad is higher than the characteristic impedance of the same line at the board trace supporting top surface. Thus, there is an impedance discontinuity resulting in ringing occurring in a data signal transmitted through that chip interconnection bonding wire in this conventional configuration.

If the characteristic impedance of the chip interconnection between the chip and the board is greater than the characteristic impedance of the printed circuit board traces and the chip bonding pads in a chip interconnection elevation configuration, then another configuration featuring a smaller distance between the chip bonding pad surface and the board ground plane leads to a reduction in the characteristic impedance mismatch at both ends of the chip interconnection. Achieving a better impedance matching follows from having the characteristic impedance at both ends of the chip interconnection being essentially the same.

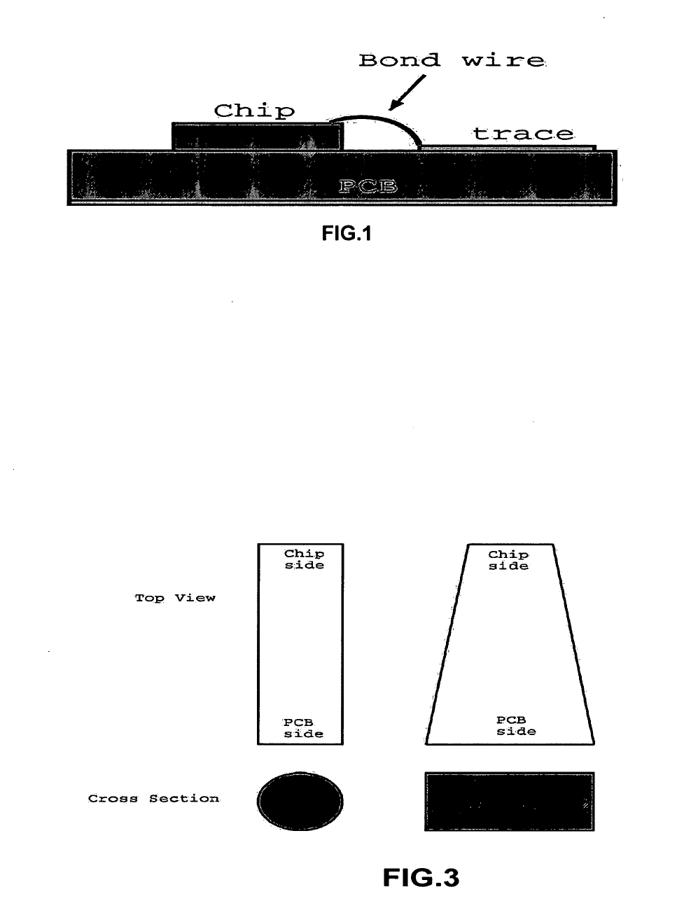

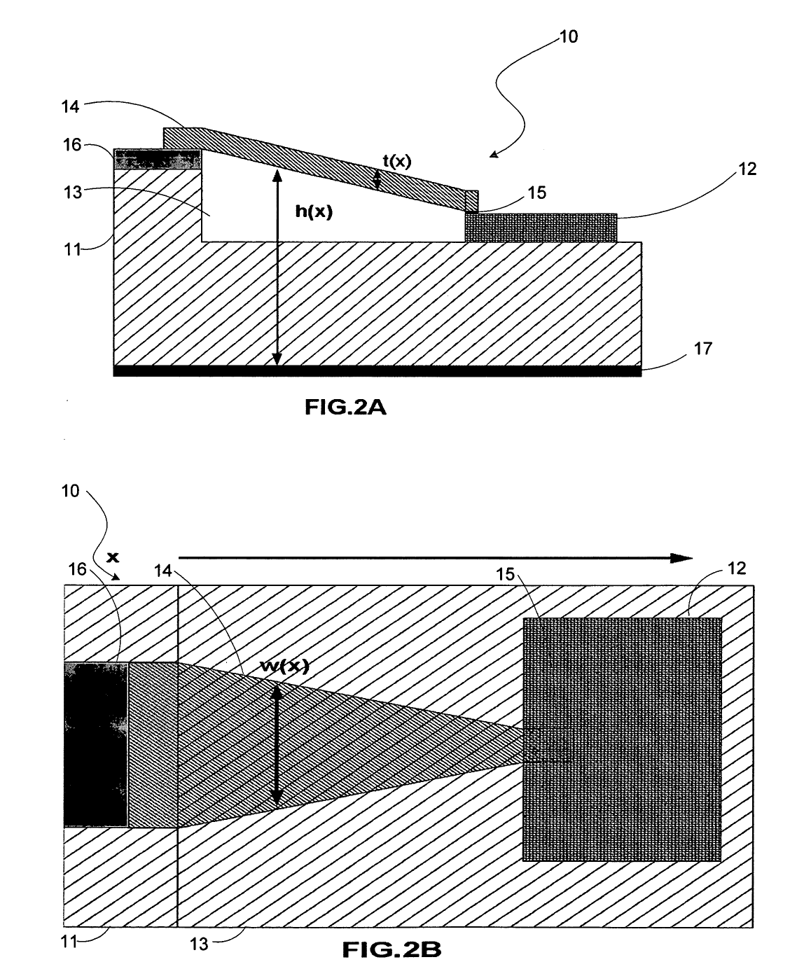

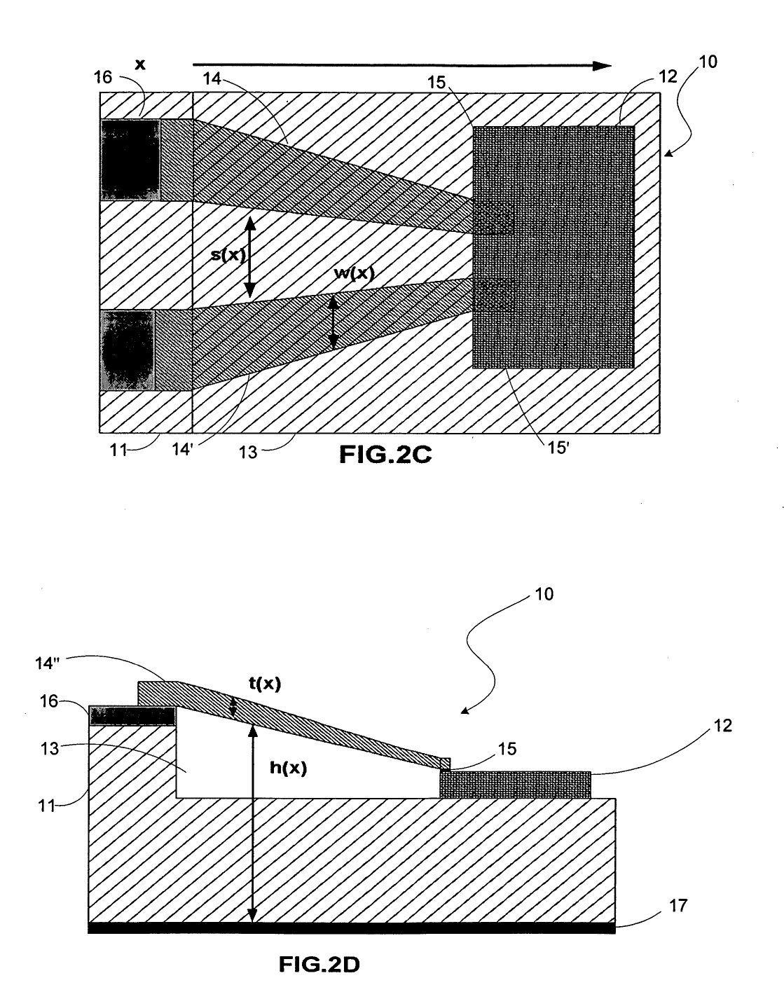

An integrated circuit chip and supporting substrate configuration, 10, for this purpose provides a printed circuit board, 11, with a chip, 12, in a cavity, 13, in that board such that the elevation of the chip bonding pad surface is below the elevation of the board top surface supporting traces by a distance as shown in FIG. 2A. An interconnection conductor, 14, extends at an inclination from a bonding pad, 15, on chip 12 to a trace, 16, on board 11 over a ground plane conductor, 17, provided across the bottom of board 11. Although the chip top surface elevation shown there is below the board trace supporting surface, in other situations the chip top surface elevation might not be chosen to be below the board top surface elevation. The chip top surface elevation can be chosen to be above the board top surface elevation but still below what the chip top surface elevation is in the conventional board mounting configuration presented in FIG. 1 in which the whole of the chip is on the board top trace supporting surface. The chip interconnection path from the board to the chip is configured in such a way that satisfies the chip interconnection performance desired, while at the same time complying with all physical, mechanical and fabrication process constraints.

In the situation in which the chip top or bonding pad surface elevation is lower than the board top trace supporting surface elevation, the chip interconnection angles upward to thereby avoid touching the chip edge, and leaves a spacing margin between it and the chip even if the chip interconnection has the shape of a straight line. This particular assembly configuration has the advantage of not having to connect the chip interconnection so as to leave it with an arc shape in allowing the chip interconnection to be placed in a path that is close to a straight line.

In the conventional board mounted assembly of FIG. 1, the mounted chip is entirely elevated above the trace supporting surface forming the top of the printed circuit board. This presents the need for the spatial path of bonding wires to follow the shape of an arc. The arc-shaped bonding wire path, as seen in FIG. 1, has this disadvantage of connecting the bond wire between the chip and the board in an arc shape which increases the discontinuity in the chip interconnection characteristic impedances, and so leads to more noise in the signals transmitted thereover.

In differential signal transmission, a chip interconnection pair of conductors is used to connect the printed circuit board traces to corresponding chip bonding pads such as is shown in FIG. 2C where interconnection conductor 14 is shown paired with a further interconnection conductor, 14′. The side view of FIG. 2A remains the same for the configuration shown in FIG. 2C as it is for the configuration shown in FIG. 2B and similar structure portions in each are labeled with the same numerical designators. Usually, the chip bonding pad edges and the edges of the trace pads on the board are parallel to each other. Typically then, the board traces near the trace pads are perpendicular to the chip edge from a top layout view.

A center line can be defined as the linear axis that extends from the center point between the adjacent board trace bonding pads for this chip interconnection pair to the center point between the corresponding chip bonding pads. Each conductor wire of the chip interconnect pair can be considered as a mirror image of the other wire in the pair along this center line. Although the traces are usually symmetrical around the center line, the chip interconnection pair could itself alternatively be positioned at least in part on one side of the center line. Typically the spacing between adjacent board trace pads might be an order of magnitude greater than the spacing between adjacent chip pads. The position of the chip interconnection in a cross section more or less perpendicular to its extent is a function of the deviation of the wires in the conductor pair from the center line along the path of the chip interconnection from the board to the chip, the elevation of the chip interconnection relative to the board top trace supporting surface, and the distance that a selected cross section is located from either the board or chip toward the other.

Optimized variation in the elevation of wedge wires also improves the electrical performance of the circuit. This can be seen in the smaller variation in Zₒ along the path of the wedge. This results in reducing the distortion of signal pulses as they propagate along the chip interconnection transmission line.

The cross section of the conductor plays an important role in the performance of a chip interconnection. As indicated above, the goal is to minimize any impedance mismatch or discontinuity in the chip interconnection along the spatial path thereof. One source of impedance mismatch between the board traces, the chip interconnections, and the chip bonding pads occurs because of the abrupt change in self and mutual inductances and capacitances of the chip interconnections at the junctions of the board trace pads and the chip interconnections, and at the junctions of the chip bonding pads and the chip interconnections. The board trace pad cross sections are rectangular while the chip interconnection bonding wire cross sections are circular, and each of these geometries will usually lead to the corresponding structure having different self and mutual inductances and capacitances. A match can be made to occur if the width and thickness of the board trace pads cross section is selected such that they produce the same Zₒ, Z_{odd}, and Zₑᵥₑₙ for the selected radius for the corresponding bond wires with circular cross sections. In addition, a board trace pad having a rectangular cross section behaves differently at high signal frequencies than a bonding wire having a circular cross section because the current distributions are not the same in each of the conductors.

Choices made by selecting cross section shapes alone, whether for rectangular or circular conductors in the chip interconnections, are not enough to achieve the desired impedance matching between the chip interconnections and the pads to which they are connected. In addition, when a pair of conductors are connected in forming a chip interconnection between adjacent trace pads on a board and corresponding bonding pads on a chip, it is important to have the cross sections of the adjacent trace pads being of the same shape, and being of the same dimension. At the board trace pads, the chip interconnection conductor, or conductors, should have the same shape and dimension as the corresponding traces or trace pads. At the chip bonding pads, the chip interconnection conductor, or conductors, should have the width as the chip bonding pads. Consequently, the chip interconnection conductors between the board and the chip should have different widths at the two ends of the interconnection conductor or conductors. The thickness of the interconnection conductors is typically kept constant. Such chip interconnection conductor, or conductors, will, as a result, have a tapered shape if seen in a top view such as is shown in FIG. 3.

The variable width wedge wire shown in FIG. 3 can be connected to both a board trace or trace pad and the corresponding chip bonding pad as a tape. This can be achieved through different means. One way of doing so is to use a known automated tape bonding arrangement. In this arrangement, the tape for a chip interconnection conductor has a fixed thickness over its length. The variable width thereof over its length is drawn using commercially available layout software. Afterwards, the tape is cut according to the drawn geometry and the resulting tape piece is bonded at its ends to both the corresponding chip bonding pad and the corresponding board trace or trace pad, respectively.

Another arrangement relies upon modifying a wedge wire bonder to change the wedge width over the length thereof according to selected dimensions. The thickness of the wedge wire is typically kept the same over this length. The width of the wedge is varied by changing the side apertures of the wedge bonder.

The thickness of the chip interconnection conductor is often kept constant. However, the thickness can be allowed to vary along the spatial path of the chip interconnection conductors to provide better matching of the characteristic impedances in some situations. Decreasing the thickness of a chip interconnection conductor, 14″, along the spatial path from the board to the chip as shown in FIG. 2D would result in increasing the chip interconnection inductance, and hence the characteristic impedance thereof, and therefore should be avoided unless there is also a need to adjust the chip interconnection characteristic impedance.

A chip interconnection can extend from a board trace or trace pad to the corresponding chip bonding pad in air or alternatively through another electrically insulating material. The relative dielectric constant of air is 1, while the relative dielectric constants of such other insulation materials can be 2, 3, or any other practical value available in such materials. The insulating material can be for example an epoxy, polyimide or any other material that has a higher dielectric constant than air. If the characteristic impedance of the chip interconnection transmission line is too large in air, then it can be reduced by submerging the chip interconnection conductor, or conductors, in such other insulating materials. The insulating material in such an arrangement increases the self and mutual capacitances of the chip interconnection and hence reduces the characteristic impedance of the line. The relative dielectric constant is then available to be taken into consideration as a further parameter for use in improving the impedance matching of a chip interconnection transmission line in that material and the pads which it connects.

One closed form representation approximating the relationship between the characteristic impedance along a chip interconnection conductor between the points to which it is bonded to an integrated circuit chip and to the printed circuit board trace of the board on which that chip is mounted as described above in connection with FIGS. 2 and 3 is given by

$${Z}_{o} = 87 \frac{ln \frac{5.98 h ( x )}{0.8 w ( x ) + t ( x )}}{\sqrt{1.41 + {ɛ}_{r}}} .$$

Here, h(x) is the separation distance between the interconnection conductor and the conductive layer across the substrate serving as the system ground plane, i.e., the conductive layer on the bottom of the printed circuit board in FIGS. 2A and 2D, as a function of the horizontal distance x between the interconnect starting at the bond point of the interconnect on the trace and proceeding toward the chip, w(x) is the width of the interconnection conductor as a function of that distance as shown in FIGS. 2B and 2C, t(x) is the thickness of the interconnection conductor as a function of that distance as shown in FIGS. 2A and 2D, and εᵣ is the effective dielectric constant of the material or materials between the interconnection conductor over the separation distance. (In FIG. 2C, s(x) is the varying distance between interconnection conductors 14 and 14′ as a function of distance x.)

The foregoing description is drawn to arrangements in which one or more monolithic integrated circuit chips are mounted on a printed circuit board or boards. However, the invention chip interconnection structures are useable with other kinds of chip mounts such as flexible circuits or chip interconnection modules.

Modeling mathematically a wedge or a bond wire to obtain a more detailed representation thereof is a three spatial dimensions problem typically solved using a finite element analysis approach. The elevation, spacing between interconnection conductors in a pair, and wedge or wire cross sections are taken into consideration in modeling the round bond wire and the rectangular cross section wedge, whether of fixed or spatially variable dimensions in calculating the chip interconnection parasitic resistance, capacitance, inductance, and conductance for the chip interconnection. These parameters are calculated for each chip interconnection conductor in the model. The mutual parasitic parameters are also calculated between the various conductors. These parameters are arranged in a set of R, L, G, and C matrices termed the RLGC matrix. The RLGC matrix indicated above was calculated for the transmission line model taking R and G as functions of frequency. From the resulting RLCG matrix, the characteristic impedances Zₒ of these chip interconnection structures were calculated.

The impedance matching problem can be formulated as a constrained optimization problem. The objective function is the minimization of the impedance variation along the path of the chip interconnection from the PCB to the chip, while the optimization variables are bound by the design constraints and physical limitations of the circuit.

In the case of a flat wedge like chip interconnection, the design dimensions of interest are width, and thickness t of the interconnection conductor. In other cases where the cross-sectional shape of the chip interconnection is trapezoidal, an arc, or any other shape, each particular shape dimensions are considered the design optimization variables.

One optimization variable is the width w(x) as a function of distance x from the PCB to chip. wₘᵢₙ is the minimum width of the chip interconnection conductor. This dimension is bounded by the processing equipment available, and the chip pad size. wₘₐₓ is the maximum width of the interconnect. This dimension is bounded by the processing equipment available, and the PCB trace width.

A second optimization variable is the thickness t(x) as a function of distance from the PCB to chip. tₘᵢₙ is the minimum thickness of the chip interconnection conductor which is bounded by the processing equipment available. tₘₐₓ is the maximum thickness of the interconnection conductor. The bounds on tₘₐₓ are the processing equipment available and the maximum interconnection conductor thickness available, in addition to the maximum horizontal mutual capacitance that can be tolerated between adjacent chip interconnections.

A third optimization variable is the elevation d(x) as a function of distance from the PCB to chip. dₘᵢₙ is the minimum elevation of the chip interconnection that is bounded by the processing equipment available to perform the bonding. dₘₐₓ is the maximum elevation of the interconnection conductor. dₘₐₓ is bounded by the processing equipment available to perform the bonding, and the maximum interconnection conductor thickness that can be built on top of the chip pad.

Another optimization variable is the material in which the chip interconnection is submerged. It can be air, epoxy material, polyimide, or any other material that provides the optimal dielectric constant for the material filling the volume where the interconnection conductor passes through. Therefore, define εᵣ as the dielectric constant of the insulating material. The effect of different values of εᵣ is to increase the self and mutual parasitic capacitance of the chip interconnection and decrease the characteristic impedance of the interconnection to ground, such that a minimal characteristic impedance mismatch is achieved. Note that in certain cases, the characteristic impedance needs to change by only a small amount. The minimum relative dielectric constant, εᵣ₋ₘᵢₙ of a material is for air and is equal to 1. εᵣ₋ₘₐₓ is achieved by the availability of the material with the highest dielectric constant.

The chip interconnection design and impedance matching problem can be viewed as an optimization problem. The objective function is to minimize the impedance mismatch subject to the design constraints that are imposed on the circuit. Such constraints emanate from the physical limitations of the dimensions of the elements designed, and the other relevant dimensions and parameters. As an example, the PCB trace width and chip interconnection cross-section dimensions may have bounds set by manufacturing and other considerations. As a result, the design problem can be viewed as a constrained optimization problem.

The choice of the optimization function depends on the figure of merit desired in the design process. The optimization objective function can be the minimization of a difference function or functions. This means one or more figures of merit can be used. In addition, a specific weight, or cost function can be designated to each figure of merit to enforce the relative importance of one or more figures of merit over the others.

One figure of merit that can be calculated for the chip interconnection is the difference in characteristic impedance between the PCB level Zₒ(x_{PCB}) and the chip level Zₒ(x_{chip}). This can be written as
Z_{mismatch}=Zₒ(x_{chip})−Zₒ(x_{PCB})

Another figure of merit can be the integral of the difference of the characteristic impedance of the line Zₒ, at any x to an ideal value Z_{ideal}(x) at that same x.

Z_{ideal}(x) can be a constant value such as the impedance of the PCB trace. Z_{ideal}(x) can also be a linear interpolation, like a straight line between the two impedance values. It can also be a higher order polynomial, or a nonlinear interpolation function. The impedance points can be (x_{PCB},Zₒ(x_{PCB})), and (x_{chip},Zₒ(x_{chip})).

In general, the difference between two functions can be define as the integral

$${\int }_{x} \vert F ( x ) \vert$$

over x where F is the function that constitutes the difference in impedance. The optimization problem can be formulated as:

$$min {\int }_{x} \vert \frac{{Z}_{o} ( x ) - {Z}_{o - ideal} ( x ) }{{Z}_{o - ideal} ( x )} \vert such that$$

$${w}_{min} \leq w ( x ) \leq {w}_{max}$$

$${t}_{min} \leq t ( x ) \leq {t}_{max}$$

$${d}_{min} \leq d ( x ) \leq {d}_{max}$$

$${ɛ}_{min} \leq ɛ ( x ) \leq {ɛ}_{max}$$

where x spans the interconnection conductor path, and Z_{o-ideal}(x)≠0 at any x. Notice that the objective function can be in the form

$$min {\int }_{x} \vert {Z}_{o} ( x ) - {Z}_{o} ( {x}_{PCB} ) \vert$$

which takes PCB edge as the reference value for comparison.

A third figure of merit can be defined as the square root of the integral of the square of the difference function; i.e.

$$\sqrt{{\int }_{x} {( F ( x ) )}^{2}}$$

Then the problem can be formulated as

$$min \sqrt{{\int }_{x} {( \frac{{Z}_{o} ( x ) - {Z}_{o - ideal} ( x ) }{{Z}_{o - ideal} ( x )} )}^{2} } such that$$

$${w}_{min} \leq w ( x ) \leq {w}_{max}$$

$${t}_{min} \leq t ( x ) \leq {t}_{max}$$

$${d}_{min} \leq d ( x ) \leq {d}_{max}$$

$${ɛ}_{min} \leq ɛ ( x ) \leq {ɛ}_{max}$$

where Z_{o-ideal}(x)≠0 at any x. In this case, the objective function minimizes the percentage difference in the characteristic impedance. Note that the objective function can be the combination of any suitable measurement functions.

There are several figures of merit that can be used for comparing the different structures in terms of the characteristic impedances. The figures of merit and/or a combination of them and/or other figures of merit can provide an indication of the performance of the chip interconnection of the COB configuration.

A set of simulation runs were performed to demonstrate the improvement of the signal quality due to the invention. In addition, comparative analysis is provided for the case of the round bond wire upwards to chip and the variable width wedge. The simulation basis information and results appear in the following tables and in the graphs provided in the figures.

TABLE 1
Simulation Example Specifications

| Parameter | Units | Value |
|---|---|---|
| Conductivity of PCB metal | 1/(Ohm · m) | 5.72E+007 |
| Conductivity of bond wire | 1/(Ohm · m) | 5.72E+007 |
| Relative dielectric constant of | | 4.1 |
| material | | |
| Relative dielectric constant of | | 3.05 |
| material of PCB | | |
| Thickness of dielectric layer | m | 1.50E−003 |
| of PCB | | |
| Loss tangent of PCB dielectric | m | 2.70E−003 |
| material | | |
| Width of fixed width wedge | m | 2.50E−005 |
| Height of fixed width wedge | m | 1.25E−005 |
| Length of interconnect | m | 2.40E−003 |
| Distance between inner edges of | m | 2.50E−004 |
| PCB pads | | |
| Distance between inner edges of | m | 2.50E−005 |
| chip pads | | |
| Thickness of bond pad of chip | m | 1.00E−006 |
| Thickness of ground plane of PCB | m | 2.50E−005 |
| Thickness of bond pad of PCB | m | 1.25E−005 |
| Width of bond pad of chip | m | 6.50E−005 |
| Width of bond pad of PCB | m | 2.50E−004 |
| Length of PCB micro-strip line | m | 1.00E−002 |
| Elevation of chip-top above PCB- | m | 1.09E−003 |
| top in PUC case | | |
| Elevation of chip-top below PCB- | m | 3.50E−004 |
| top in PDC case | | |

TABLE 2
Definitions of Terms

| | |
|---|---|
| Chip on Board | A direct attachment method to mount |
| (COB) | an unencapsulated die to a printed |
| | circuit board (or MCM-L). Wire bonding |
| | is typically used to connect the |
| | signals to the circuit board, and |
| | an epoxy encapsulation over the die and |
| | wires provide environmental protection. |
| Characteristic | The terminal impedance that a |
| impedance | transmission line tends towards as its |
| | length tends to infinity. |
| Bond wire | A conductive wire that connects a |
| | semiconductor die to an external |
| | circuit. |
| Printed Circuit | A circuit for electronic apparatus |
| Board | made by depositing conductive material |
| | in continuous paths from terminal- |
| | to-terminal on an insulating surface. |
| | PCB's are used in final production |
| | of electronic products, but maybe used |
| | during the prototype phase as well. |
| Eye Diagram | A graph of the bit stream vs time. |
| | The time window is only the bit pulse |
| | width in time or a multiple of it. |
| | The bit stream is forced to be plotted in |
| | this window with each bit is overlayed |
| | on top of the previous bit pulse |
| | width. |
| V_source_near | Voltage signal applied differentially |
| | at the near end of the interconnect |
| | pair |
| PUC | The path the interconnect travels |
| | from PCB Upwards to the Chip |
| PFC | The path the interconnect travels |
| | from PCB Flat to the Chip |
| PDC | The path the interconnect travels |
| | from PCB Downwards to the Chip |
| RBW | Round bond wire |
| FWW | Fixed width wedge |
| VWW | Variable width wedge |

TABLE 3
Simulation results: Characteristic Impedance Magnitude

| | RBW | RBW | | | |
|---|---|---|---|---|---|
| | PUC | PUC | RBW | FWW | VWW |
| Parameter | (Diel) | (Air) | PDC | PDC | PDC |
| Magnitude of | 50.6 | 50.6 | 50.6 | 201.6 | 141.1 |
| characteristic impedance | | | | | |
| at PCB edge (Ohm) | | | | | |
| Magnitude of | 122.6 | 122.6 | 21.74 | 133.0 | 133.0 |
| characteristic impedance | | | | | |
| at chip pad edge (Ohm) | | | | | |
| Minimum magnitude | 50.6 | 50.6 | 21.74 | 133.0 | 133.0 |
| of characteristic | | | | | |
| impedance (Ohm) | | | | | |
| Maximum magnitude | 181.8 | 310.9 | 251.1 | 143.3 | 143.3 |
| of characteristic | | | | | |
| impedance (Ohm) | | | | | |
| Magnitude of | 34.1 | 34.1 | 31.1 | 139.0 | 82.9 |
| odd-mode | | | | | |
| characteristic | | | | | |
| impedance at | | | | | |
| PCB edge (Ohm) | | | | | |
| Magnitude of | 85.3 | 86.4 | 14.5 | 80.3 | 80.3 |
| odd-mode | | | | | |
| characteristic | | | | | |
| impedance at | | | | | |
| chip edge (Ohm) | | | | | |
| Minimum magnitude | 34.1 | 34.1 | 14.5 | 73.4 | 80.3 |
| of odd-mode | | | | | |
| characteristic | | | | | |
| impedance (Ohm) | | | | | |
| Maximum magnitude of | 126.2 | 210.2 | 185.1 | 139.1 | 86.8 |
| odd-mode | | | | | |
| characteristic | | | | | |
| impedance (Ohm) | | | | | |
| Magnitude of even-mode | 86.4 | 86.4 | 78.3 | 282.5 | 282.7 |
| characteristic | | | | | |
| impedance at | | | | | |
| PCB edge (Ohm) | | | | | |
| Magnitude of even-mode | 214.7 | 216.1 | 37.0 | 133.0 | 255.8 |
| characteristic | | | | | |
| impedance at | | | | | |
| chip-edge (Ohm) | | | | | |
| Minimum magnitude of | 82.8 | 86.3 | 37 | 255.0 | 222.5 |
| even-mode | | | | | |
| characteristic | | | | | |
| impedance (Ohm) | | | | | |
| Maximum magnitude of | 221.8 | 378.9 | 289.7 | 241.7 | 241.7 |
| even-mode | | | | | |
| characteristic | | | | | |
| impedance (Ohm) | | | | | |

TABLE 4
Percentage Difference of Characteristic Impedances Relative
to the Characteristic Impedance of the Trace

| | RBW PUC | RBW PUC | RBW | FWW | VWW |
|---|---|---|---|---|---|
| Parameter | (Diel) | (Air) | PDC | PDC | PDC |
| Minimum percentage difference of the | −62.9 | −62.9 | −84.1 | −7.5 | −7.4 |
| characteristic impedance magnitude | | | | | |
| relative to, and normalized to the | | | | | |
| magnitude of the characteristic | | | | | |
| impedance of the PCB trace (100%) | | | | | |
| Maximum percentage difference of the | 34.0 | 127.8 | 84.0 | 27.7 | 6.04 |
| characteristic impedance magnitude | | | | | |
| relative to, and normalized to the | | | | | |
| magnitude of the characteristic | | | | | |
| impedance of the PCB trace (100%) | | | | | |
| Minimum percentage difference of the | −57.7 | −57.7 | −82.0 | −9.0 | −9.0 |
| odd-mode characteristic impedance | | | | | |
| magnitude relative to, and normalized | | | | | |
| to the magnitude of the characteristic | | | | | |
| impedance of the PCB trace (100%) | | | | | |
| Maximum percentage difference of the | 56.6 | 160.8 | 129.6 | 72.6 | 7.7 |
| odd-mode characteristic impedance | | | | | |
| magnitude relative to, and normalized | | | | | |
| to the magnitude of the characteristic | | | | | |
| impedance of the PCB trace (100%) | | | | | |
| Minimum percentage difference of the | −48.2 | −48.2 | −53.1 | −1.0 | −1.0 |
| even-mode characteristic impedance | | | | | |
| magnitude relative to, and normalized | | | | | |
| to the magnitude of the characteristic | | | | | |
| impedance of the PCB trace (100%) | | | | | |
| Maximum percentage difference of the | 32.9 | 127.1 | 73.6 | 25.7 | 7.5 |
| even-mode characteristic impedance | | | | | |
| magnitude relative to, and normalized | | | | | |
| to the magnitude of the characteristic | | | | | |
| impedance of the PCB trace (100%) | | | | | |

TABLE 5
Characteristic Impedance Difference Metrics

| | RBW | RBW | | | |
|---|---|---|---|---|---|
| | PUC | PUC | RBW | FWW | VWW |
| Parameter | (Diel) | (Air) | PDC | PDC | PDC |
| The integral of the characteristic | 31.2 | 98.3 | 38.9 | 7.4 | 4.1 |
| impedance difference relative to, | | | | | |
| and normalized to the | | | | | |
| characteristic impedance of the | | | | | |
| PCB trace (100%) | | | | | |
| The integral of the odd-mode | 40.0 | 119.9 | 53.8 | 10.0 | 4.8 |
| characteristic impedance | | | | | |
| difference relative to, and | | | | | |
| normalized to the odd-mode | | | | | |
| characteristic impedance of the | | | | | |
| PCB trace (100%) | | | | | |
| The integral of the even-mode | 28.4 | 93.9 | 32.1 | 3.5 | 1.7 |
| characteristic impedance | | | | | |
| difference relative to, and | | | | | |
| normalized to the even-mode | | | | | |
| characteristic impedance of the | | | | | |
| PCB trace (100%) | | | | | |

Several types of graphs are referred to in the following. One type is the time domain response of a random bit stream applied to the chip interconnection. A Non-Return-to-Zero (NRZ) random bit stream is generated with a maximum run length of 6. The first data rate is 10 Gbit/s with a rise time tr=50 ps, and pulse width=50 ps. The other data rate is 50 Gbit/s with a rise time tr=10 ps, and pulse width=10 ps. The bit stream has an unbalanced number of 0's and 1's. The choice of unbalanced code results in more visible distortion in the signal due to DC line wandering. The other graph type is the eye diagram which is the overlay of the bit stream on a time window set by the pulse width size.

Note: the term “period” refers to the period of the maximum clock that can be recovered from the signal. In the NRZ case, the clock is half the bit rate. For example, period=40 ps refers to the maximum clock frequency, 25 GHz, that can be recovered from the 50 Gbit/s NRZ bit stream. The rise time tr=10 ps, and pulse width=10 ps. The time slot for each bit is the combined rise time and pulse width of 20 ps. The tr=50 ps case, refers to the 5 GHz maximum clock frequency that can be recovered from the 10 Gbit/s NRZ bit stream. The rise time tr=50 ps, and pulse width=50 ps. The time slot for each bit is the combined rise time and pulse width of 100 ps.

Tables 3, 4 and 5 provide characteristic impedance values for the interconnect. In addition, they provide the impedance variations of the interconnection normalized relative to the PCB trace impedance. The tables show that the minimum impedance variations occur for the variable width wedge when the interconnection conductor path is from the PCB downwards to the chip. The worst case for the round bond wire is when the interconnection extends from PCB upwards to the chip. The impedance variation was maximum.

Several cases were simulated. For the round bond wire, two COB configurations were studied. First, the chip is placed on top of the PCB, and the bond wire travels upwards from the PCB to the chip. Second, the chip top is placed below the elevation of the PCB trace top. Please refer to Tables 3, 4 and 5 especially the columns corresponding to Round Bond Wire (RBW) connected upwards to the chip (PUC) and Round Bond Wire connected downwards to the chip (PDC) throughout the subsection.

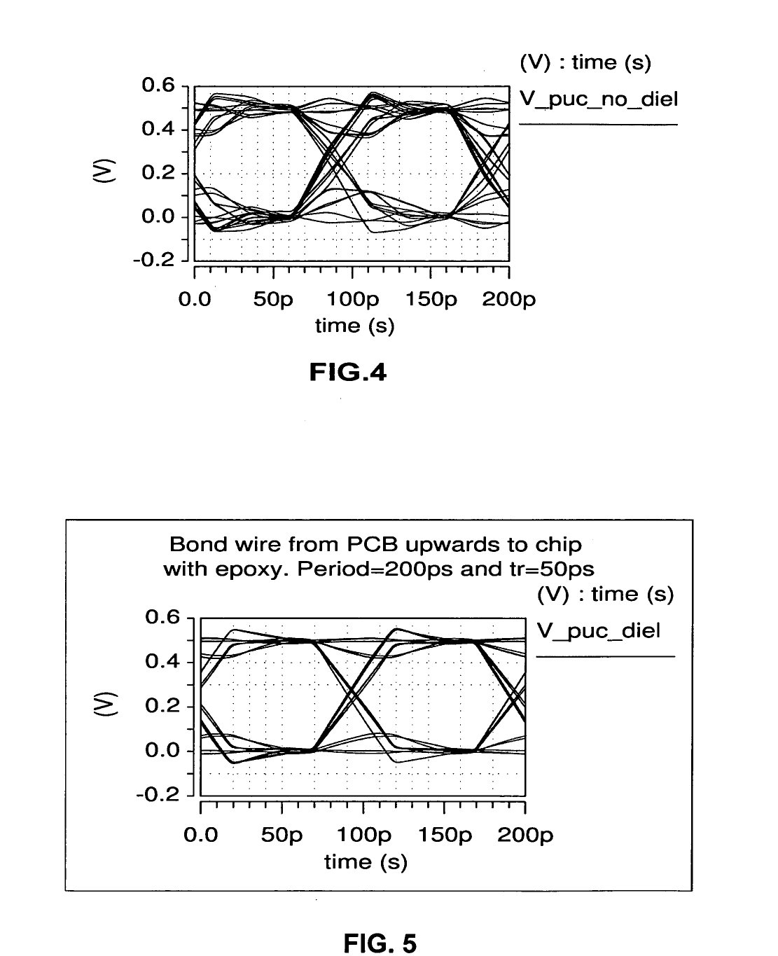

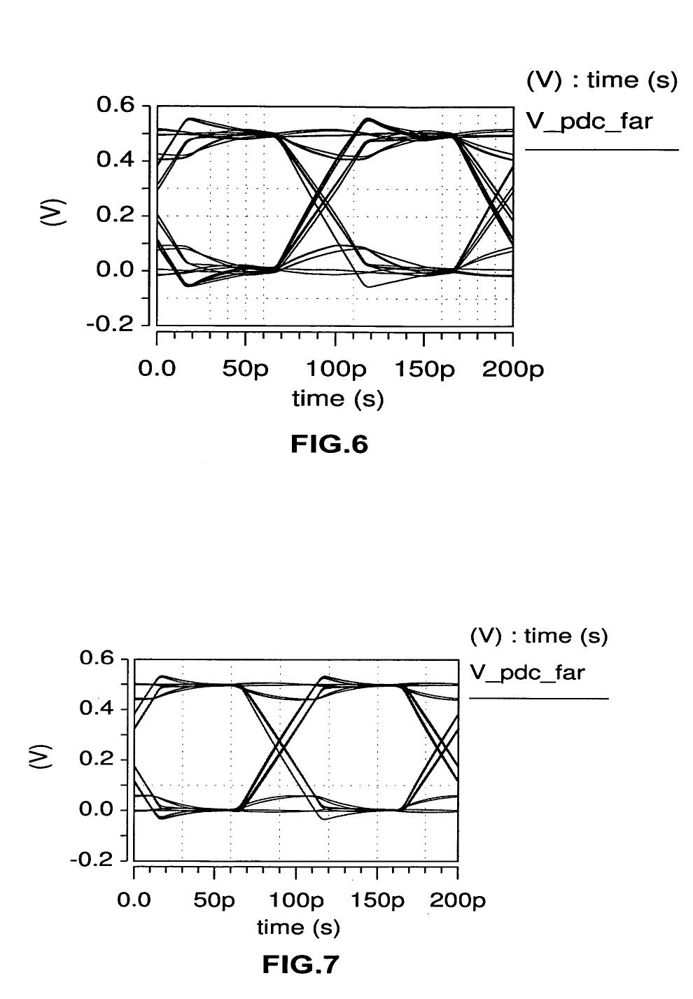

FIGS. 4 and 6 show the eye diagrams for tr=50 ps. In FIG. 4, there is a definite eye opening although inter-symbol interference (ISI) is visible in the reduction of the eye opening. As the chip elevation is decreased, less ISI and wider eye opening can be achieved horizontally and vertically, as in FIG. 6.

FIGS. 9 and 11 show the eye diagrams for tr=10 ps. For the V_puc_far case in FIG. 9, the eye is closed due to the severe ISI and signal distortion. In the V_pdc_far case in FIG. 11, less ISI is visible and a small eye opening can be achieved horizontally and vertically.

In the following analysis, a comparison is made between the round bond wire, fixed width wedge, and variable width wedge cases of chip interconnection shapes. In this analysis, the elevation of the chip is chosen to be below the PCB trace elevation. Please note that in the fixed width wedge case, the width of the wedge is equal to the chip pad width. Please refer to Tables 3, 4 and 5, especially the columns describing connections down to the chip (PDC) with round (RBW), fixed-width wedge (FWW) or variable width wedge (VWW) wires throughout the subsections.

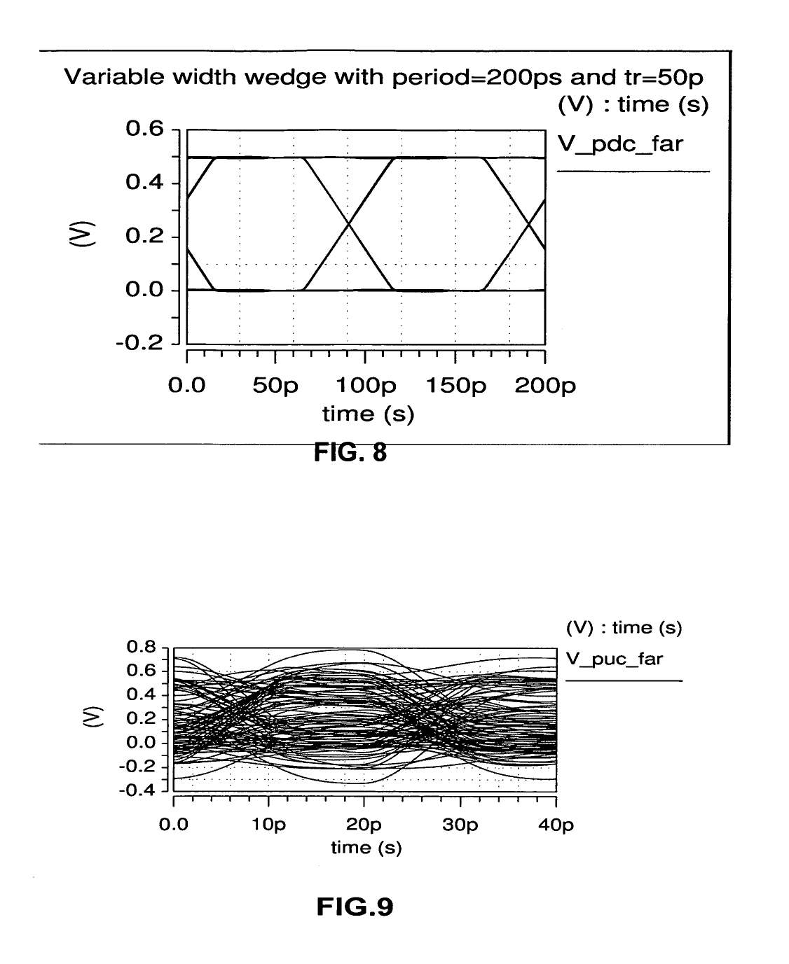

FIGS. 6, 7, and 8 show the eye diagrams for tr=50 ps. For the round bond wire in FIG. 6, there is a definite eye opening although inter-symbol interference (ISI) is visible in the eye opening. When the chip interconnection conductor cross-section changes from the round cross section and becomes closer in geometry to the PCB trace cross section, the eye opening is improved as shown in the fixed width wedge case in FIG. 7. When the width varies from the PCB trace width on one end, and the chip pad width on the other end, the improvement in the eye opening was significant. This can be seen in FIG. 8 where no ISI or signal distortion is visible, and signal quality is superb.

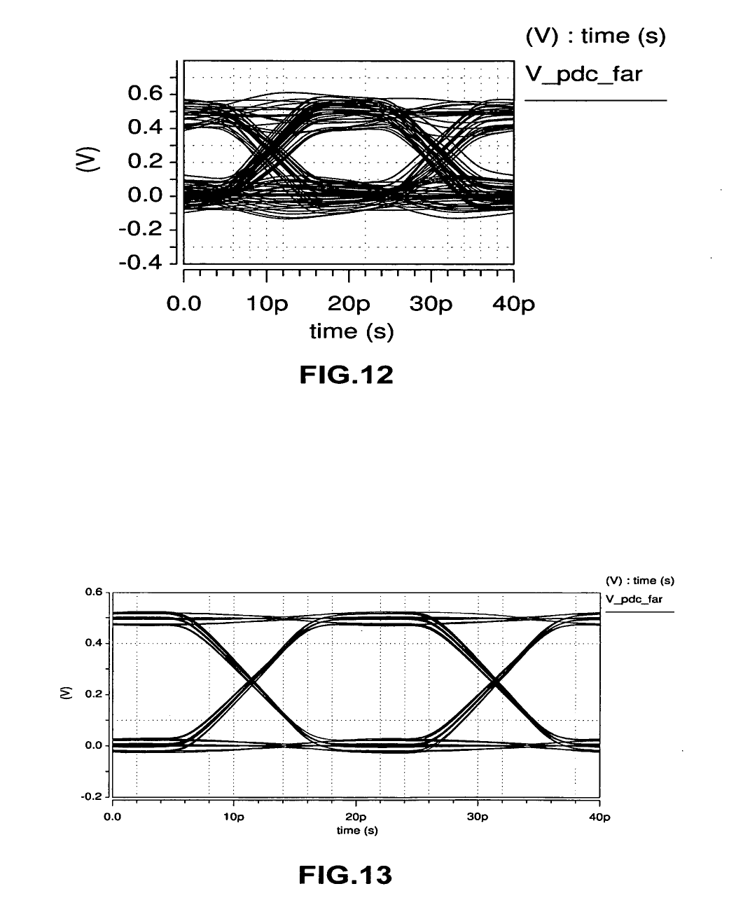

FIGS. 11, 12, and 13 show the eye diagrams for tr=10 ps. For the round bond wire in FIG. 11, the eye is open but suffers from considerable ISI and signal distortion. When the chip interconnection conductor cross section changes from the round cross section and becomes closer in geometry to the PCB trace cross section, the eye opening is widened horizontally and vertically. However, it still suffers from considerable ISI and signal distortion, and the eye opening is narrow. When the chip interconnection conductor width varies from the PCB trace width at the PCB edge, to the chip pad width at the chip edge, the eye opening is significantly improved. This can be seen in FIG. 13 where the eye opening is wider horizontally and vertically with a small ISI and distortion.

It can be seen that changing the chip interconnection cross section from the round bond wire to fixed width wedge, and to the variable width wedge, improves the eye diagram. In the low elevation case, the eye opening was widened, and the ISI and signal distortion was decreased significantly.

The example given in this section is where the chip is elevated above the PCB and a round bond wire is used. A comparative analysis is provided for the case where the round bond wire travels through air, and through insulating material. Please refer to Tables 3-5 especially the second (dielectric), and third (air) columns throughout next subsection.

FIGS. 4 and 5 show the eye diagrams for tr=50 ps. FIG. 4 represents the case where the round bond wire is surrounded by air, while FIG. 5 represents the case where the round bond wire is submerged into a dielectric material. FIG. 4 shows more distortion of the signal than when the bond wire is submerged into the insulating material. The eye opening in FIG. 6 is wider horizontally and vertically.

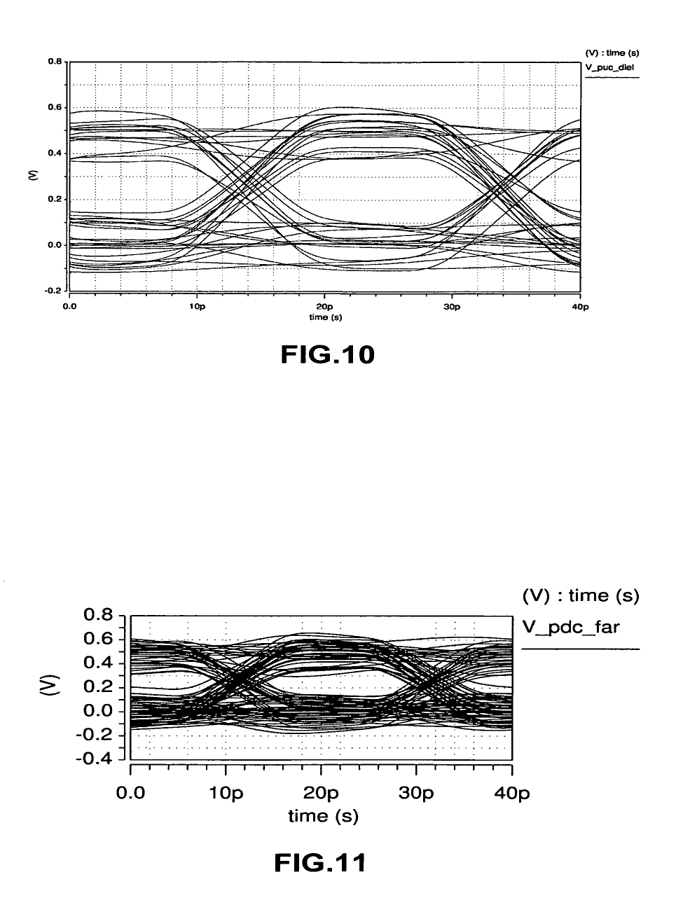

For the tr=10 ps case, FIGS. 9 and 10 show the eye diagrams for the bond wire surrounded by air and bond wire submerged in dielectric material, respectively. In FIG. 9, the eye is closed. This is due to the large characteristic impedance discontinuities along the path of the bond wire from the PCB to the chip. In FIG. 10, there is a definite eye opening and less distortion and ISI is visible in the eye. This is due to less mismatch in the characteristic impedance of the bond wire along its path from the PCB to the chip.

It can be seen that changing the relative dielectric constant of the medium, surrounding the chip interconnection conductor along its path from the PCB to chip, markedly improves the eye diagram. This was done by reducing the characteristic impedance variations of the bond wire. In general, each case should be studied on its own to utilize the insulating material that minimizes the mismatching problem.

It is noticed that the variation in the characteristic impedance is decreased considerably in the case of the variable width wedge in comparison to the case of round bond wire. In the following discussion, a comparative analysis is performed between the case where a round bond wire travels upwards from the PCB to the chip, and the case where a variable width wedge travels from the PCB downwards to the chip. Please refer to Tables 3, 4 and 5, especially the third and sixth columns throughout next subsection. Column 3 contains data from a conventional round bond wire COB method and column 6 shows data from combined methods using both variable width wires and reduced chip elevation. FIG. 4 shows the eye diagram for the round bond wire from the PCB trace upwards to the chip for tr=50 ps. There is a definite eye opening although inter-symbol interference (ISI) is visible in the reduction of the eye opening. FIG. 8 shows the eye opening for the variable width wedge from the PCB trace downwards to the chip for tr=50 ps. The eye opening is perfect due to no ISI and due to the minimum discontinuities in the characteristic impedance of the variable wedge COB configuration.

For tr=10 ps, FIG. 9 shows the eye diagram for the round bond wire case. There is no eye opening due to severe inter-symbol interference and signal distortion. FIG. 13 shows the eye opening for the variable width wedge case. The eye opening is almost perfect with minimal ISI due to the minimum discontinuities in the characteristic impedance of the variable wedge COB configuration. The variable width wedge COB configuration passes the simulation test of very high bit rates (50 Gbit/s) while the bond wire COB configuration fails.

It can be seen in both the presented figures and tables that the variable width wedge has improved performance relative to the round bond wire. There is minimal mismatch evident in the impedance diagram and the improvement in the eye diagram is clearly evident.

The variable width wedge configuration and the other chip mounting structural modifications from conventional structures described above individually or in combination have various applications in high-speed circuit design where there is a need to transmit data bits at high rates to and from the chip. These structures can be used, for instance, in the chip interconnections between high data rate microprocessors or digital signal processors, or both, and the memory chips and high speed peripheral devices often used therewith. Because traditional chip interconnects will often distort rapidly varying signals, maximum operational data rates are often limited by chip interconnection related issues. Use of the chip interconnection structures of the present invention will allow higher data rates with improved data integrity in comparison to traditional wire bonding methods.

Another application is in rapidly operating network switches and backplanes. Gigabit rate serializer and deserializer (SerDes) I/O devices are used for these applications and the devices must employ significant pre-emphasis techniques in the transmitter or equalization techniques in the receiver, or both, to overcome chip interconnection related signal loss and intersymbol interference. Use of the present invention chip interconnection structures will significantly simplify the design and requirements of SerDes components in these systems.

A further application is in high data rate optical networks used between the various optical transmit and receive modules and the associated SerDes devices. In multi-gigabit network applications such as SONET (Synchronous Optical Network) that adhere to the OC-768 and related data formats, all instances of jitter must be minimized. Use of the present invention chip interconnect structures will significantly reduce jitter resulting from intersymbol interference in comparison with conventional bonding wire interconnection arrangements.

Broadband wireless systems can also benefit from the present invention chip interconnection structures in that interconnections between components becomes much less of a problem in limiting performance. While conventional wire bonding methods can sometimes be used successfully in high frequency wireless applications by using narrow frequency band signaling or by very careful “tuning” of chip interconnection related parasitic capacitances and inductances, these inventive structures will allow use of signals having very broad frequency ranges and with no need for parasitic elements tuning.

Although the present invention has been described with reference to preferred embodiments, workers skilled in the art will recognize that changes may be made in form and detail without departing from the spirit and scope of the invention.

1. An electronic circuit component mounting system for mounting electronic circuit components on a substrate, said system comprising:
an electronic circuit component having an electrically conductive bonding pad on an interconnection surface thereof,
a substrate having a trace supporting surface having an electrically conductive trace thereon, and further having a mounting location therein for said component spaced apart from an electrically conductive layer across therefrom with said component being supported on said mounting location so as to leave said interconnection surface of said component at a distance from said layer differing from that distance between said trace supporting surface and said layer, and
an electrically conductive interconnection conductor having one end thereof in a bond with said pad and an opposite end thereof in a bond with said trace to thereby result in a separation distance between said interconnection conductor and said layer varying between said bonds, said interconnection conductor having a distance there across perpendicular to that path thereof between said bonds that varies with said separation distance.

2. The system of claim 1 wherein said interconnection conductor is formed of a plate of substantially constant thickness with a shape in a plane perpendicular thereto approximating an outline of a four sided polygon that has two opposite relatively shorter sides and two relatively longer sides with said two longer sides being nonparallel.

3. The system of claim 1 wherein said interconnection conductor is formed of a plate with a shape in a plane perpendicular to its thickness approximating an outline of a four sided polygon and having a thickness between said bonds that varies with said separation distance.

4. The system of claim 1 wherein said interconnection conductor is a first interconnection conductor and further comprising an electrically conductive second interconnection conductor adjacent to said first interconnection conductor but separated therefrom by an isolating distance, said second interconnection having one end thereof in a bond with another pad on said interconnection surface and an opposite end thereof in a bond with another trace on said trace supporting surface to thereby result in a separation distance between said second interconnection conductor and said layer varying between said bonds therewith, said second interconnection conductor having a distance there across perpendicular to that path thereof between said bonds that varies with said separation distance.

5. The system of claim 1 wherein said separation distance of said interconnection conductor occurring at one of said bonds differs from that occurring at that remaining one of said bonds, and wherein a said distance across said interconnection conductor perpendicular to that path thereof between said bonds occurring at one of said bonds differs from that occurring at that remaining one of said bonds.

6. The system of claim 1 further comprising at least one solid material positioned between said interconnection conductor and said mounting location.

7. The system of claim 4 wherein said isolating distance varies with said separation distance.

8. An electronic circuit component mounting system for mounting electronic circuit components on a substrate, said system comprising:
an electronic circuit component having adjacent first and second electrically conductive bonding pads on an interconnection surface thereof,
a substrate having a trace supporting surface having adjacent first and second electrically conductive traces thereon, and further having a mounting location therein for said component with said component being supported on said mounting location, and
first and second electrically conductive interconnection conductors with said first conductive interconnection having one end thereof in a bond with said first pad and an opposite end thereof in a bond with said first trace, and with said second conductive interconnection having one end thereof in a bond with said second pad and an opposite end thereof in a bond with said second trace, to thereby result in an isolating distance between said first and second interconnection conductors that varies between said bonds, said first and second interconnection conductors each having a distance there across perpendicular to that path thereof between said bonds and substantially perpendicular to said isolating distance that varies between said bonds.

9. The system of claim 8 wherein said mounting location is spaced apart from an electrically conductive layer across therefrom with said component being supported on said mounting location so as to leave said interconnection surface of said component at a distance from said layer differing from that distance between said trace supporting surface and said layer to result in a separation distance between said interconnection conductor and said layer varying between said bonds, each of said first and second interconnection conductors having two different distances there across perpendicular to that path thereof between said bonds and substantially perpendicular to one another that vary between said bonds.

10. The system of claim 8 further comprising at least one solid material positioned between said first and second interconnection conductors and said mounting location.

11. The system of claim 9 wherein each of said first and second interconnection conductors is formed of a plate of with a shape in a plane perpendicular to its thickness approximating an outline of a four sided polygon that has two opposite relatively shorter sides and two relatively longer sides with said two longer sides being nonparallel, and wherein each said plate has a thickness that varies between said bonds.

12. The system of claim 9 wherein said separation distance of each of said first and second interconnection conductors occurring at one of said bonds thereof differs from that occurring at that remaining one of said bonds thereof, and wherein a said distance across each of said first and second interconnection conductors perpendicular to that path thereof between said bonds occurring at one of said bonds differs from that occurring at that remaining one of said bonds, and wherein said isolating distance between said first and second interconnection conductors occurring at one pair of said bonds thereof adjacent to one another differs from that occurring at that remaining one pair of said bonds thereof adjacent to one another.
